(19) United States
(12) Patent Application Publication
(10) Pub. No.: US 2015/0243665 A1
(43) Pub. Date: Aug. 27, 2015

(54) SEMICONDUCTOR DEVICE AND METHOD OF MANUFACTURING SEMICONDUCTOR DEVICE

(71) Applicant: Shinichi Nakata, Tokyo (JP)

(72) Inventor: Shinichi Nakata, Tokyo (JP)

(21) Appl. No.: 14/423,686

(22) PCT Filed: Aug. 20, 2013
(86) PCT No.: PCT/JP2013/072635

§ 371 Date: Feb. 24, 2015

(30) Foreign Application Priority Data
Aug. 24, 2012 (JP) 2012-185403

(51) Int. Cl. H01L 27/108

(52) U.S. Cl. CPC H01L 27/10814; H01L 27/10897

(57) ABSTRACT

Provided is a technology which improves the manufacturing yield of a semiconductor device including a contact plug. After a contact plug (114) is buried in a first interlayer insulating film (111), the first interlayer insulating film (111) is partly removed from an upper surface side thereof to reduce the thickness thereof. After that, a second interlayer insulating film (126) is formed on the first interlayer insulating film (111) including the contact plug (114). By partly removing the second interlayer insulating film (126), a cylinder hole (117) which exposes the contact plug (114) at a bottom thereof is formed.

### TECHNICAL FIELD

This invention relates to a semiconductor device and a method of manufacturing the same.

### BACKGROUND ART

Japanese Unexamined Patent Application Publication No. 2003-7854 discloses a semiconductor memory device having a large number of capacitive elements and a method of manufacturing the same. In particular, in Japanese Unexamined Patent Application Publication No. 2003-7854, a dynamic random access memory (DRAM) is taken as an example of the semiconductor memory device in which, after a contact plug to be electrically connected to a transistor is buried in an interlayer insulating film, another interlayer insulating film is formed on an upper surface thereof via an etching stopper film, and a cylinder recess is formed therein by anisotropic etching to expose the contact plug at the bottom of the cylinder recess. Then, a capacitive element which has a stacked structure including a lower electrode, a dielectric film, and an upper electrode is formed in the cylinder recess, thereby realizing formation of the capacitive element to be electrically connected to the contact plug.

### DISCLOSURE OF INVENTION

Generally, methods of burying a contact plug in a contact hole in an interlayer insulating film include carrying out etching back, chemical mechanical polishing (CMP), or the like after a conductor film is deposited. However, the inventor of this invention reviewed and found that an electrical continuity defect and a short-circuited defect were caused between a contact plug formed by the method and another conductive portion formed thereon.

More specifically, according to the review by the inventor of this invention, it was found that, when a conductor film formed in a contact hole which had been formed in an interlayer insulating film was removed from an upper surface by etching back, a plug recess (a phenomenon that an upper surface of a plug is recessed with respect to the interlayer insulating film) was liable to occur. Further, it was found that, when an etching stopper film was formed thereafter, the thickness of the etching stopper film was not uniform at the plug recess portion, and defective etching was liable to occur later. Specifically, when an etching stopper film is formed under a state in which a plug recess occurs, the etching stopper film becomes thicker on the plug recess portion than on the interlayer insulating film. In this case, if etching is carried out with reference to the thin etching stopper film portion on the interlayer insulating film, the etching stopper film may remain at the plug recess portion, and an insulating film residual may remain in the hole. This may be a cause of an increased contact resistance or a non-conducting state between the contact plug and an upper conductor film. On the other hand, if etching is carried out with reference to the thick etching stopper film portion at the plug recess portion, the interlayer insulating film is exposed before the etching stopper film is removed. In this case, the selectivity cannot be secured at this portion, and overetching may occur. When another conductive member is exposed from the overetched interlayer insulating film, a short may be caused with an upper conductor film. As a result, it was found that, in a semiconductor device having a contact plug which was formed by the above-mentioned method, the manufacturing yield might be reduced. Further, it was found that, in a semiconductor device having a contact plug which was formed by the above-mentioned method, the reliability might be reduced.

In view of the problems described above, according to this invention, when a hole for forming a member for electrical connection to a contact plug is formed on the contact plug, an upper surface of an interlayer insulating film in which the contact plug is buried is etched back in this state, and after that, an etching stopper film and an interlayer insulating film for forming a contact hole therein are formed.

Specifically, according to one embodiment of the present invention, there is provided a semiconductor device, including: a first transistor comprising a source region and a drain region both formed on a semiconductor substrate; a first interlayer insulating film formed so as to cover the first transistor; a first contact hole formed in the first interlayer insulating film so as to expose one of the source region and the drain region; a first contact plug which is formed in the first contact hole, and which has a lower portion connected to the exposed one of the source region and the drain region, and an upper portion comprising a protruding portion which protrudes from the first interlayer insulating film; and a capacitive element formed so that an electrode thereof is electrically connected to an upper surface portion of the first contact plug.

Further, according to another embodiment of the present invention, there is provided a semiconductor device, including: a first transistor comprising a source region and a drain region both formed on a semiconductor substrate; a first interlayer insulating film formed so as to cover the first transistor; a first contact hole formed in the first interlayer insulating film so as to expose one of the source region and the drain region; a first contact plug which is formed of a conductive material in the first contact hole; a second contact hole formed in the first interlayer insulating film so as to expose another one of the source region and the drain region; a second contact plug which is formed of the conductive material in the second contact hole; a second interlayer insulating film formed on the first interlayer insulating film; a third contact hole formed in the second interlayer insulating film so as to be coincident with, in plan view, the first contact hole; a third contact plug which is formed in the third contact hole, and which has a lower portion connected to the first contact plug, and an upper portion protruding from the second interlayer insulating film; and a capacitive element comprising an electrode electrically connected to the third contact plug.

According to this invention, the manufacturing yield of the semiconductor device having a contact plug can be improved. Further, the reliability of the semiconductor device having a contact plug can be improved.

Further advantages and embodiments of this invention are described in detail in the following through description and with reference to the attached drawings.

### BRIEF DESCRIPTION OF DRAWINGS

In the accompanying drawings:

FIG. 1 is a plan view of a main part of a semiconductor device according to a first embodiment of this invention;

FIG. 2 is a sectional view of a main part of the semiconductor device according to the first embodiment of this invention;

FIG. 3 is a sectional view of the main part of the semiconductor device, for illustrating a manufacturing step according to the first embodiment of this invention;

FIG. 4 is a sectional view of the main part of the semiconductor device, for illustrating a manufacturing step that follows the step illustrated in FIG. 3;

FIG. 5 is a sectional view of the main part of the semiconductor device, for illustrating a manufacturing step that follows the step illustrated in FIG. 4;

FIG. 6 is a sectional view of the main part of the semiconductor device, for illustrating another manufacturing step that follows the step illustrated in FIG. 4;

FIG. 7 is a sectional view of the main part of the semiconductor device, for illustrating still another manufacturing step that follows the step illustrated in FIG. 4;

FIG. 8 is a sectional view of the main part of the semiconductor device, for illustrating a manufacturing step that follows the step illustrated in FIG. 6;

FIG. 9 is a sectional view of the main part of the semiconductor device, for illustrating a manufacturing step that follows the step illustrated in FIG. 8;

FIG. 10 is a sectional view of a main part of a semiconductor device according to a second embodiment of this invention;

FIG. 11 is a sectional view of a main part of the semiconductor device, for illustrating a manufacturing step according to the second embodiment of this invention;

FIG. 12 is a sectional view of the main part of the semiconductor device, for illustrating a manufacturing step that follows the step illustrated in FIG. 11;

FIG. 13 is a sectional view of the main part of the semiconductor device, for illustrating a manufacturing step that follows the step illustrated in FIG. 12;

FIG. 14 is a sectional view of the main part of the semiconductor device, for illustrating a manufacturing step that follows the step illustrated in FIG. 13;

FIG. 15 is a sectional view of the main part of the semiconductor device, for illustrating a manufacturing step that follows the step illustrated in FIG. 14;

FIG. 16 is a sectional view of the main part of the semiconductor device, for illustrating a manufacturing step that follows the step illustrated in FIG. 15;

FIG. 17 is a sectional view of a main part of a semiconductor device, for illustrating a manufacturing step according to a third embodiment of this invention;

FIG. 18 is a sectional view of the main part of the semiconductor device, for illustrating a manufacturing step that follows the step illustrated in FIG. 17;

FIG. 19 is a sectional view of the main part of the semiconductor device, for illustrating a manufacturing step that follows the step illustrated in FIG. 18;

FIG. 20 is a sectional view of a main part of a semiconductor device, for illustrating a modification according to the embodiments of this invention;

FIG. 21 is a sectional view of a main part for illustrating a problem in a semiconductor device based on which this invention is made, and illustrates a manufacturing step of the semiconductor device;

FIG. 22 is a sectional view of the main part of the semiconductor device, for illustrating a manufacturing step that follows the step illustrated in FIG. 21;

FIG. 23 is a sectional view of the main part of the semiconductor device, for illustrating a manufacturing step that follows the step illustrated in FIG. 22;

FIG. 24 is a sectional view of the main part of the semiconductor device, for illustrating a manufacturing step that follows the step illustrated in FIG. 23;

FIG. 25A is an enlarged sectional view for specifically illustrating the manufacturing step illustrated in FIG. 24;

FIG. 25B is an enlarged sectional view for illustrating a non-conducting state which occurs in a manufacturing step of the semiconductor device which follows the step illustrated in FIG. 25A; and

FIG. 25C is an enlarged sectional view for illustrating another problem which occurs in the manufacturing step of the semiconductor device which follows the step illustrated in FIG. 25A.

### DETAILED DESCRIPTION OF EXEMPLARY EMBODIMENTS

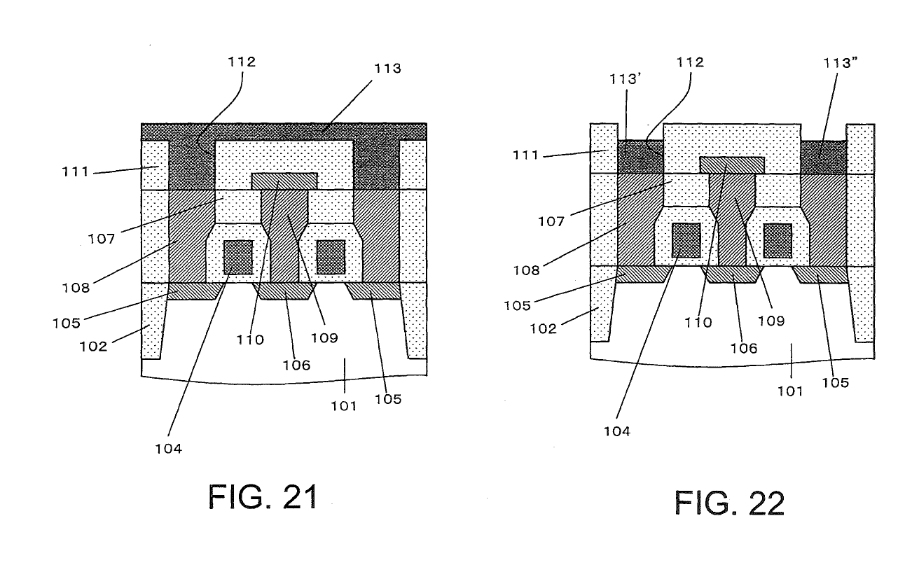

First, a technology and a problem which were reviewed by the inventor of this invention are described with reference to FIG. 21 to FIGS. 25A to 25C. With reference to FIG. 21, exemplary cell transistors (also referred to as selection transistors, hereinafter simply referred to as transistors) used in a DRAM are illustrated. In FIG. 21, two transistors are illustrated. Each of these transistors includes a source region 105 and a drain region 106 which are semiconductor regions formed in an active region defined by a shallow trench isolation (STI) 102 on a silicon substrate (semiconductor substrate) 101. The drain region 106 is shared by two transistors. Note that, similarly to the case of an ordinary field-effect transistor, the source region and the drain region do not differ in structure including the polarity, the impurity concentration, and the dimensions, and one which supplies carriers in operation is the source region while the other which collects carriers in operation is the drain region. In this embodiment, for the sake of convenience, the two regions are discriminated as the source region 105 and the drain region 106, but the two regions are interchangeable. The same can be said in the following description with regard to source regions and drain regions unless otherwise indicated. There is a gate insulating film and a gate electrode 104 which are provided in this order on a surface of the silicon substrate 101 between the source region 105 and the drain region 106.

In a cell transistor of a memory cell array such as a DRAM, each gate electrode 104 forms a part of a word line. A bit line 110 is connected to the drain region 106 via a bit line contact plug 109 (hereinafter also referred to as bit line contact). Further, a contact plug 108 is provided on each source region 105. Note that, an insulating film is formed in the STI 102, and the gate electrode 104, the contact plug 108, and the bit line contact 109 are surrounded by an insulating film.

A first interlayer insulating film 111 is formed on the contact plug 108, the bit line contact 109, and the bit line 110. A contact hole 112 is formed in the first interlayer insulating film 111. A conductor film 113 for forming a contact plug is formed in the contact hole 112 and on a surface of the first interlayer insulating film 111. The conductor film 113 is electrically connected to the contact plug 108.

In this case, two contact plugs 108 respectively provided on two source regions 105 are electrodes for two different transistors, respectively, and thus, are required to be electrically insulated from each other. Therefore, as illustrated in FIG. 22, a portion of the conductor film 113 which connects the two contact plugs 108 on the first interlayer insulating film 111 is removed by etching back, CMP, or the like. As a result, contact plugs 113′ and 113″ are formed, which are buried in the first interlayer insulating film 111, are electrically connected to the two contact plugs 108, respectively, and are formed of the conductor film (113). In this case, if the portion of the conductor film 113 on the first interlayer insulating film 111 remains after the etching, a short may be caused between the contact plugs 113′ and 113″. Therefore, there is a case in which, in order to prevent such a short between plugs, the conductor film 113 is overetched to some extent. As a result, upper surfaces of the contact plugs 113′ and 113″ become lower than an upper surface of the first interlayer insulating film 111, and a so-called plug recess may occur. FIG. 22 illustrates this state.

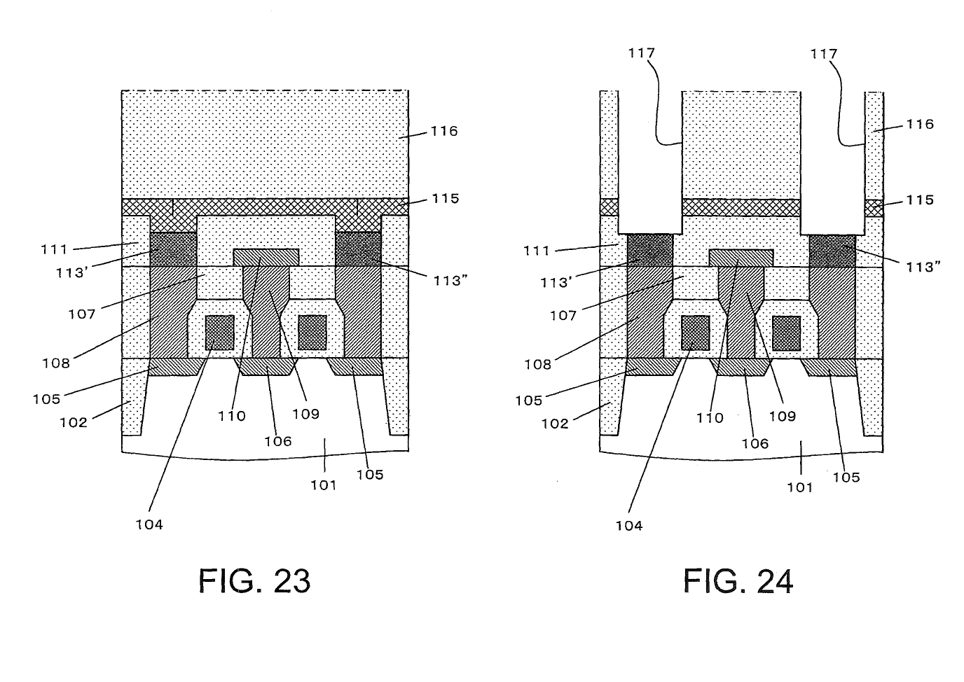

Starting from this state, in FIG. 23, an etching stopper film 115 and a second interlayer insulating film 116 are formed. There is a case in which the etching stopper film 115 is thinner on the first interlayer insulating film 111 and thicker on the contact plugs 113′ and 113″ due to the recesses which occur on the upper surfaces of the contact plugs 113′ and 113″. FIG. 23 illustrates this state.

Next, as illustrated in FIG. 24, in order to form members such as capacitive elements, portions of the etching stopper film 115 and the second interlayer insulating film 116 over the contact plugs 113′ and 113″ are removed by anisotropic etching in a thickness direction to form cylinder holes 117. In FIG. 24, a case in which the cylinder holes 117 are larger than the contact plugs 113′ and 113″ is illustrated. It is found that, in this case, if there is nonuniformity in thickness of the etching stopper film 115 due to the plug recesses, a problem described below arises when the cylinder holes 117 are formed.

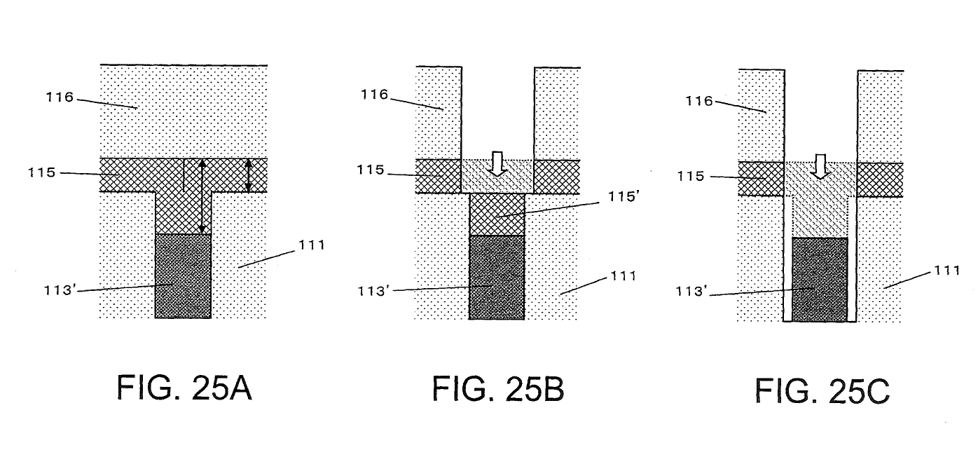

When, as illustrated in FIG. 25A, a portion of the etching stopper film 115 on the contact plug 113′ is thicker than a portion of the etching stopper film 115 on the first interlayer insulating film 111, if etching is carried out with reference to the thin portion of the etching stopper film 115 on the first interlayer insulating film 111, as illustrated in FIG. 25B, an etching stopper film 115′ may remain on the contact plug 113′, and an insulating film residual may remain in the cylinder hole 117. This may be a cause of an increased contact resistance or a non-conducting state between the contact plug 113′ and a conductor film to be formed in the cylinder hole 117 later.

On the other hand, if etching is carried out with reference to the thick portion of the etching stopper film 115 on the contact plug 113′ at which the plug recess occurs, as illustrated in FIG. 25C, even after the shoulders of the first interlayer insulating film 111 are exposed, etching of the etching stopper film 115 continues. When the etching selectivity is low between the etching stopper film 115 and the first interlayer insulating film 111 (or, when the etching rate of the first interlayer insulating film 111 is faster) or the like, the first interlayer insulating film 111 may be overetched. When another conductive member is exposed from the overetched first interlayer insulating film 111, a short may be caused with a conductor film to be formed in the cylinder hole 117 later.

Embodiments of this invention which can solve the above-mentioned problems are described in the following with reference to the attached drawings. In the following description, a DRAM is taken as an example, but it goes without saying that the technical scope of this invention is not construed to be limited thereto.

### First Embodiment

First, a first embodiment of this invention is described.

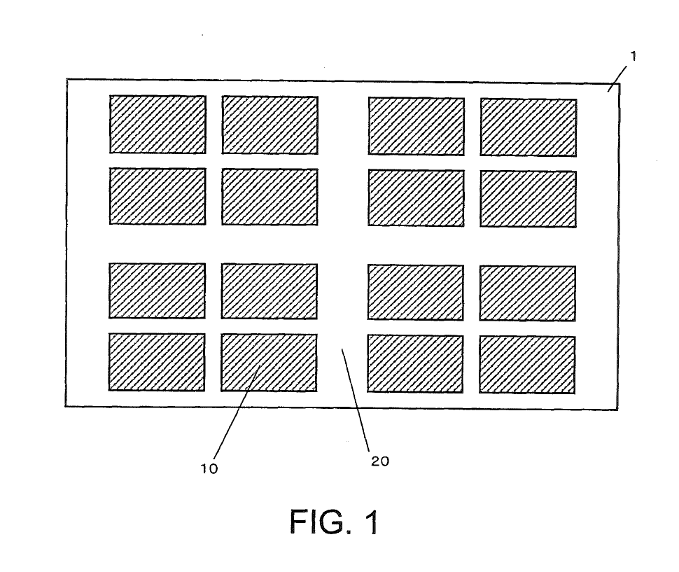

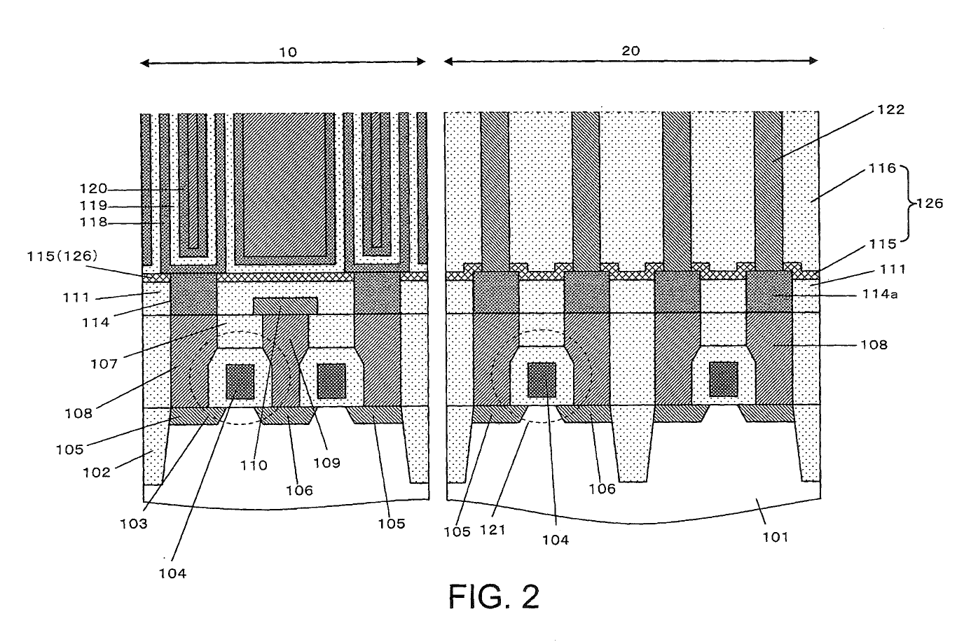

FIG. 1 is a plan view of a main part of a semiconductor device according to the first embodiment of this invention. A semiconductor chip 1 which forms the illustrated semiconductor device includes a memory cell region 10 and a peripheral circuit region 20. FIG. 2 is a sectional view of a main part of the semiconductor device according to the first embodiment of this invention.

With reference to FIGS. 1 and 2, in this case, as the semiconductor device, a DRAM is illustrated by example. The DRAM includes the memory cell region 10 which itself includes a plurality of memory cells arranged in arrays, and the peripheral circuit region 20 which itself includes a peripheral circuit for controlling the operation of the plurality of memory cells. The memory cell region 10 and the peripheral circuit region 20 are arranged so as to be adjacent to each other with an element isolation region therebetween. In FIG. 2, among the plurality of memory cells included in the memory cell region 10, there are illustrated two memory cells included in an active region defined by partitioning a main surface of a silicon substrate 101 by an STI 102, and two transistors forming a peripheral circuit which is included in the peripheral circuit region 20.

Each of cell transistors 103 forming the two memory cells illustrated in the memory cell region 10 is similar to the two cell transistors described with reference to FIG. 21. Members designated by the same reference symbols as those in FIG. 21 have similar structures, and thus, detailed description thereof is omitted here. In this case, a contact plug 114 is formed on the contact plug 108.

A capacitive element (capacitor) is formed in a hole provided in an etching stopper film 115 and an interlayer film 116 which are formed on the first interlayer insulating film 111. The illustrated capacitor is formed by stacking, in the hole in the interlayer film 116, a lower electrode (electrode film) 118, a dielectric film 119, and an upper electrode 120 in this order. The lower electrode 118 is held in contact with the etching stopper film 115 and is connected to the contact plug 114 at the bottom thereof. Further, the contact plug 114 is connected to the source region 105 of the transistor 103 via the contact plug 108 provided under the contact plug 114. Further, in the illustrated example, the upper electrode 120 is covered with an electrode film to which a power supply potential (for example, a ground potential) is supplied, and the electrode film is also provided between two capacitive elements.

Further, the two transistors illustrated in the peripheral circuit region 20 are peripheral transistors 121 respectively arranged in active regions defined by partitioning the main surface of the silicon substrate 101 by the STI 102. Each peripheral transistor 121 has a structure similar to that of the above-mentioned cell transistor 103 except that the drain region 106 is not shared. In this case, a contact plug 114a for a peripheral transistor is formed on each contact plug 108.

The etching stopper film 115 and the interlayer film 116 such as a silicon oxide film are formed on the first interlayer insulating film 111 in the peripheral circuit region 20. Through holes are formed so as to pierce the interlayer film 116 and the etching stopper film 115, and a contact plug 122 for a peripheral transistor is formed in each through hole.

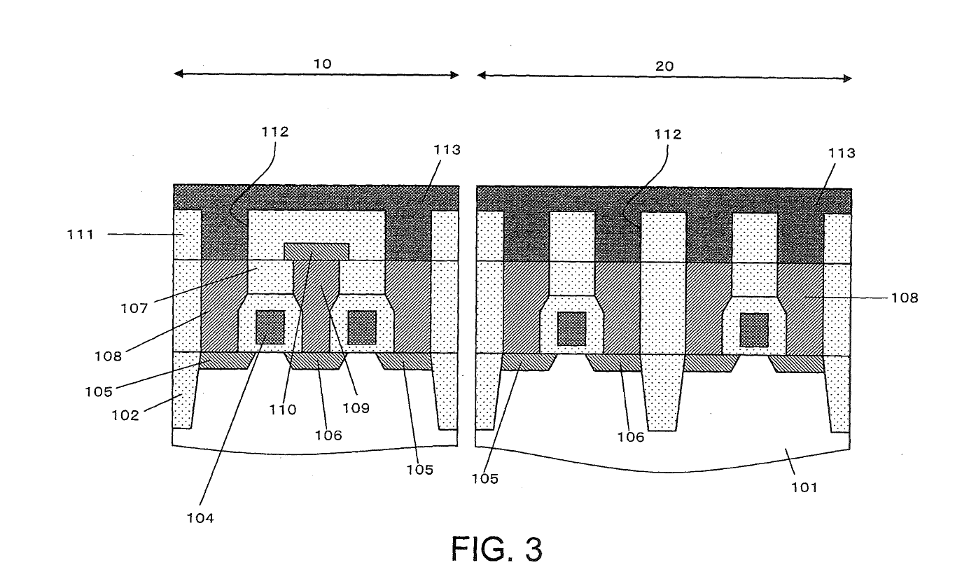

Manufacturing steps of the semiconductor device described with reference to FIG. 1 and FIG. 2 are now described with reference to FIG. 3 to FIG. 9.

First, as illustrated in FIG. 3, the STI 102 which is an insulating separation portion in the shape of shallow grooves is formed by a well-known method in the memory cell region 10 and the peripheral circuit region 20 on the silicon substrate 101 to define the active regions. Then, field-effect transistors (the cell transistors 103 in the memory cell region 10 and the peripheral transistors 121 in the peripheral circuit region 20) are formed in the active regions by a well-known method. After that, a surface of the substrate is covered with an interlayer insulating film, and the contact plug 108 and the bit line contact plug 109 are formed in the interlayer insulating film. For example, the interlayer insulating film can be formed using an insulating material mainly formed of silicon oxide, silicon nitride, or the like, and each contact plug can be formed using a conductive material mainly formed of conductive polysilicon (also referred to as polycrystalline silicon), tungsten, or the like. A well-known method such as chemical vapor deposition (CVD) or sputtering may be applied to the film formation. Unless otherwise indicated, the same can be said with regard to methods of forming various kinds of films in the following. In this case, the structure is formed by forming a contact hole in the interlayer insulating film by well-known photolithography, anisotropic etching, or the like (hereinafter referred to as well-known patterning method) and burying a conductive material therein (for example, carrying out etching back after deposition).

Next, the bit line 110 is formed on an upper surface of the bit line contact plug 109 provided in the drain region 106 above the cell transistor 103 in the memory cell region 10. In this case, the bit line 110 formed of a conductive material is formed by forming a film of a conductive material so as to cover the interlayer insulating film including the upper surface of the bit line contact plug 109, and after that, carrying out processing by a well-known patterning method. As the conductive material, a material mainly formed of conductive polysilicon, tungsten, or the like can be used.

Next, the first interlayer insulating film (first insulating film) 111 is deposited in the memory cell region 10 and the peripheral circuit region 20. After that, the first interlayer insulating film 111 is partly removed to form the contact hole (first opening) 112. The contact hole 112 is formed so that at least a part of the contact plug 108 is exposed at the bottom thereof by piercing the first interlayer insulating film 111 from the upper surface to a lower surface thereof at a location coincident with the contact plug 108 in a lower layer of the first interlayer insulating film 111 in plan view. In this case, the first interlayer insulating film 111 is partly removed so that the contact hole 112 described above is formed by a well-known patterning method.

Next, the conductor film (first conductive film) 113 is deposited from the upper surface side of the first interlayer insulating film 111. This forms the conductor film 113 from within the contact hole 112 over the upper surface of the first interlayer insulating film 111.

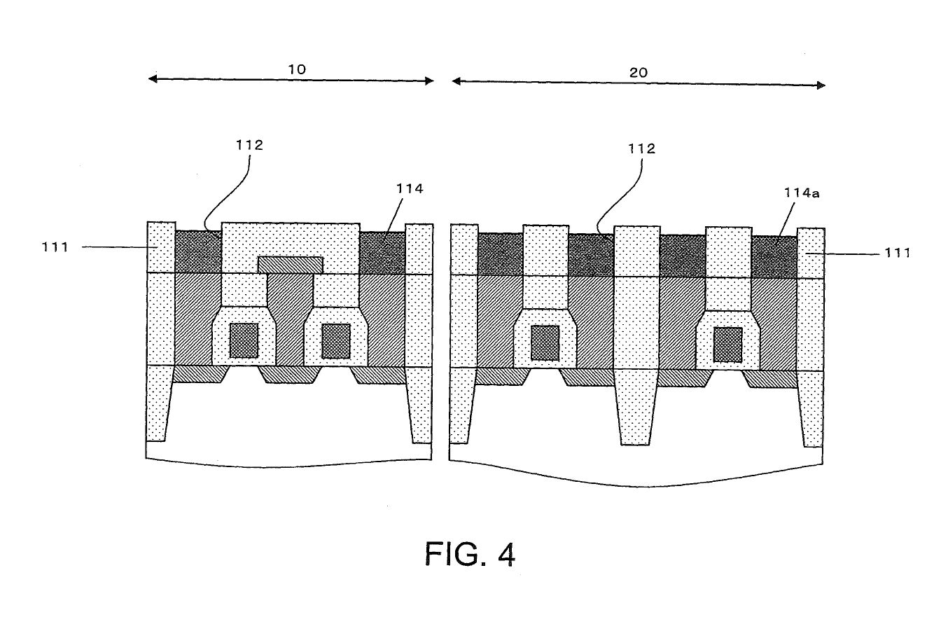

Next, as illustrated in FIG. 4, portions of the conductor film 113 which are formed on the upper surface of the first interlayer insulating film 111 are removed to form the contact plugs (conductive plugs) 114 which are formed by burying the conductor film 113 in the contact holes 112. More specifically, the film thickness is reduced by, for example, etching back from the upper surface side of the conductor film 113 which is formed by the step illustrated in FIG. 3. By stopping the etching back after the first interlayer insulating film 111 is exposed, the above-mentioned step can be realized. Etching back is a step of carrying out highly anisotropic etching in the thickness direction of the target film without a mask. In this case, CMP may be applied instead of etching back. Note that, in this step, simultaneously with the contact plugs 114 in the memory cell region 10, the contact plugs (conductive plugs) 114a for peripheral transistors are formed in the contact hole 112 in the peripheral circuit region 20.

In the above-mentioned step of forming the contact plugs 114 and 114a, in order to avoid a short between the contact plugs 114 and 114a, it is preferred not to leave the conductor film 113 between the upper surfaces of the first interlayer insulating film 111. Therefore, as illustrated in FIG. 4, the etching back of the conductor film 113 is not stopped immediately after the first interlayer insulating film 111 is exposed, but a little later than that. In other words, overetching to some extent is carried out. As a result, upper surfaces of the contact plugs 114 and the contact plugs 114a for peripheral transistors are lower than the upper surfaces of the first interlayer insulating film 111, and so-called plug recesses are formed. In order to remove more completely the conductor film 113 on the upper surfaces of the first interlayer insulating film 111, the time period of the etching back becomes longer and the plug recesses become deeper.

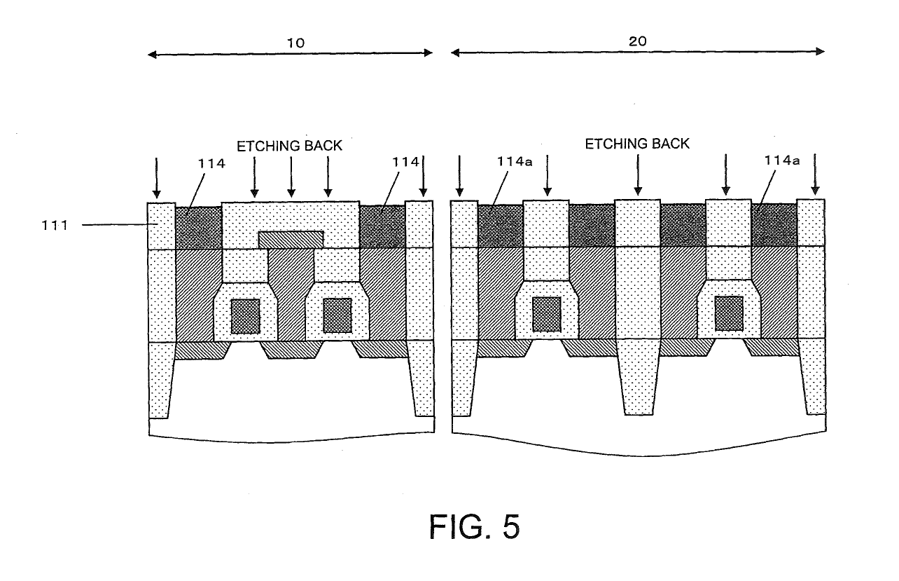

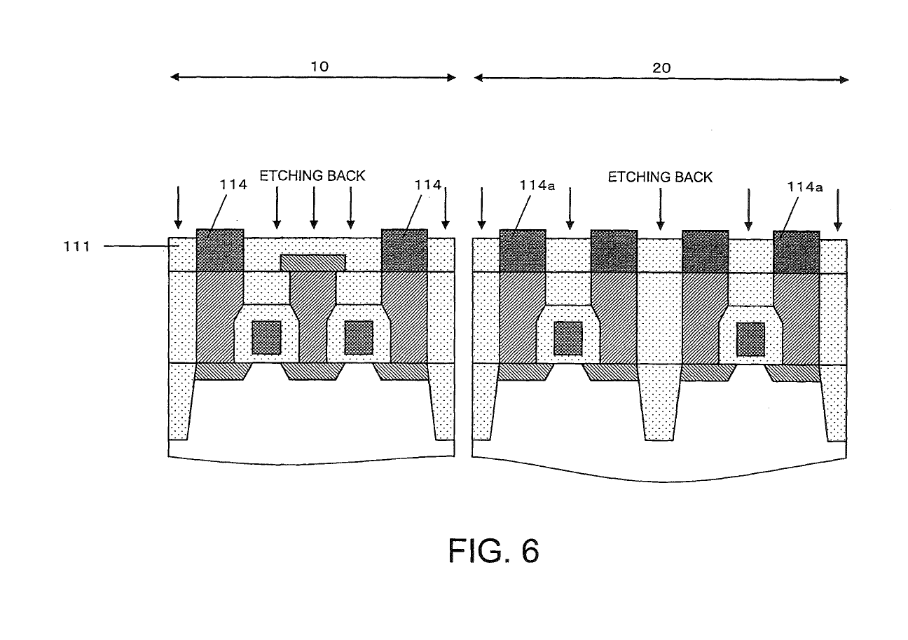

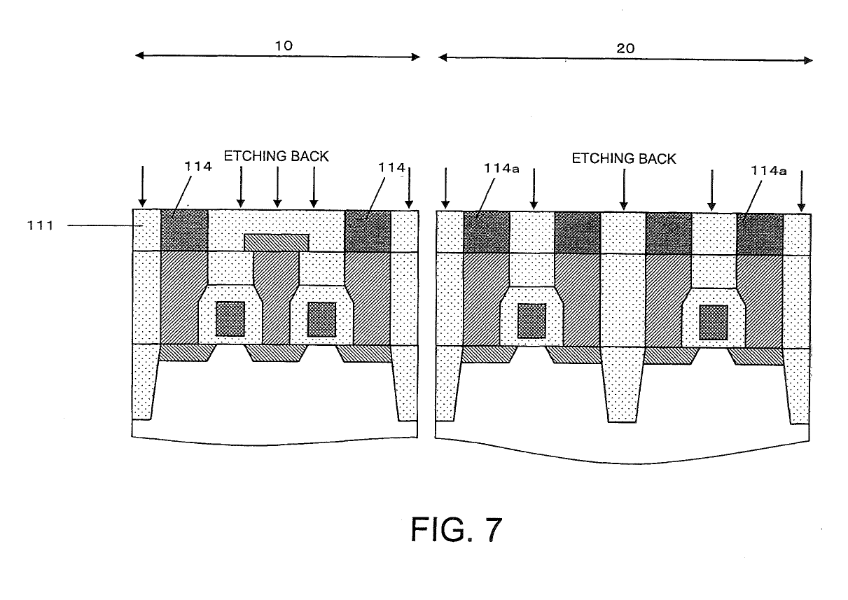

After that, as illustrated in FIG. 5, by partly removing the first interlayer insulating film 111 from the upper surface side thereof, the thickness of the first interlayer insulating film 111 is reduced. In this case, the above-mentioned step is realized by etching back the first interlayer insulating film 111 from the upper surface side thereof. As a result, the upper surfaces of the first interlayer insulating film 111 become closer to the upper surfaces of the contact plugs 114 and 114a. In other words, the plug recesses on the upper surfaces of the contact plugs 114 and 114a become shallower. In this case, as illustrated in FIG. 6, the first interlayer insulating film 111 may be etched back to an extent that the upper surfaces of the first interlayer insulating film 111 become lower than the upper surfaces of the contact plugs 114 and 114a. In other words, the etching back may be carried out to an extent that the upper surfaces of the contact plugs 114 and 114a protrude from the upper surfaces of the first interlayer insulating film 111. As a result, the plug recesses on the upper surfaces of the contact plugs 114 and 114a are eliminated. Further, as illustrated in FIG. 7, the first interlayer insulating film 111 may be etched back to an extent that the upper surfaces of the first interlayer insulating film 111 are flush with the upper surfaces of the contact plugs 114 and 114a. This eliminates the plug recesses on the upper surfaces of the contact plugs 114 and 114a, and, at the same time, the planarization of the upper surfaces of the first interlayer insulating film 111 is improved.

In this way, in this step, after forming the contact plugs 114 and 114a in the first interlayer insulating film 111, by reducing the thickness of the first interlayer insulating film 111, the amount of the plug recesses can be reduced or eliminated. This can reduce an inconvenience in forming the cylinder holes 117 later. An action and an effect are described in detail below. Steps subsequent thereto are described as being continued from the step illustrated in FIG. 6 (that is, a structure in which the contact plugs 114 and 114a protrude from the first interlayer insulating film 111).

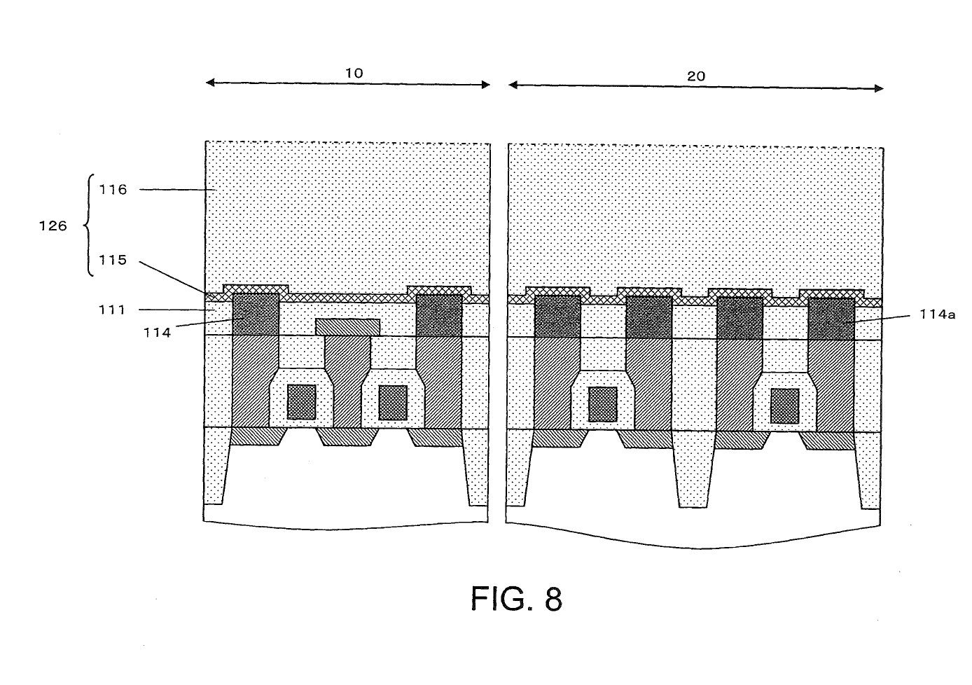

Next, as illustrated in FIG. 8, a second interlayer insulating film (second insulating film) 126 is formed on the upper surfaces of the first interlayer insulating film 111 and on the contact plugs 114 and 114a to cover the contact plugs 114 and 114a. In this case, as the second interlayer insulating film 126, for example, a film formed by stacking two kinds of insulating films (the etching stopper film 115 and the interlayer film 116) is formed. In this case, the etching stopper film 115 is thinner than the interlayer film 116. Further, as a predetermined condition in anisotropically etching the interlayer film 116 in the thickness direction, the etching stopper film 115 is formed of a material of a lower etching rate than that in the case of the interlayer film 116. As such a material, for example, the interlayer film 116 mainly formed of silicon oxide and the etching stopper film 115 mainly formed of silicon nitride can be adopted. The second interlayer insulating film 126 is deposited in the memory cell region 10 and in the peripheral circuit region 20 in the same step. In this case, the etching stopper film 115 and the interlayer film 116 are formed so as to have the same thicknesses, respectively, in the memory cell region 10 and in the peripheral circuit region 20.

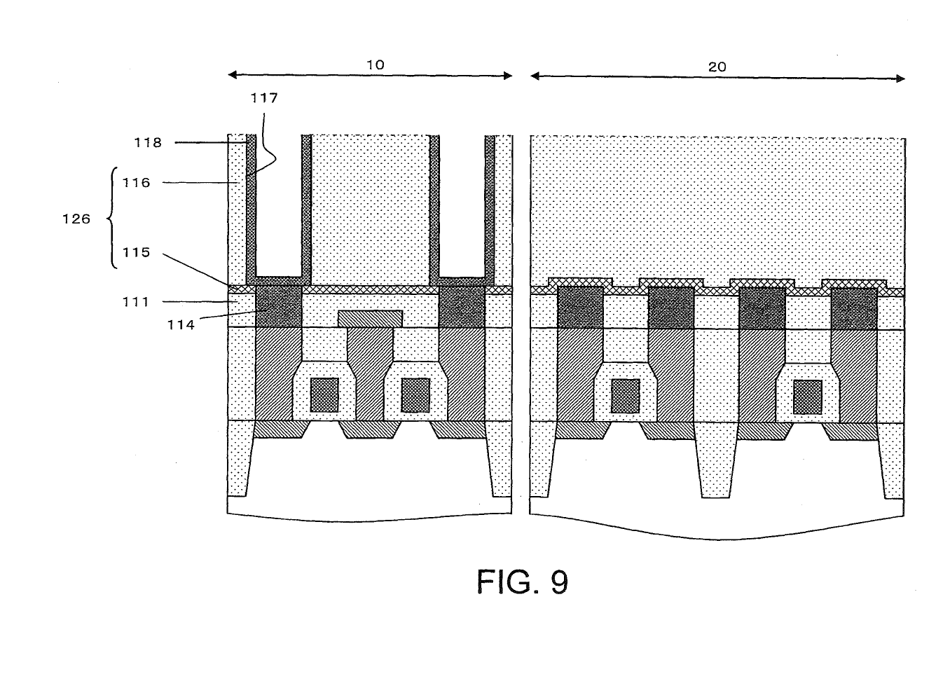

Next, as illustrated in FIG. 9, by partly removing the second interlayer insulating film 126, the cylinder hole (second opening) 117 which partly exposes the contact plug 114 in the memory cell region 10 is formed. In this case, the second interlayer insulating film 126 is partly removed so as to form the cylinder hole 117 at the bottom of which at least a part of the contact plug 114 is exposed by piercing the second interlayer insulating film 126 from an upper surface to a lower surface thereof, at a location in the second interlayer insulating film 126 in the memory cell region 10 which is coincident with, in plan view, the contact plug 114 formed in the first interlayer insulating film 111. The cross-sectional area of the cylinder hole 117 is larger than the cross-sectional area of the contact plug 114. When the second interlayer insulating film 126 has a two-layer structure including the etching stopper film 115 and the interlayer film 116, by anisotropically etching the interlayer film 116 in the thickness direction with a high etching selectivity with respect to the etching stopper film 115, effectively stopping the etching at the etching stopper film 115, and then etching the etching stopper film 115, the above-mentioned step can be realized.

According to this embodiment, as described with reference to FIG. 5, FIG. 6, and FIG. 7, the amount of the plug recess of the underlayer contact plug 114 can be reduced or eliminated. This can reduce or eliminate the difference between the thickness of the second interlayer insulating film 126 on an upper surface of on the contact plug 114 and the thickness of the second interlayer insulating film 126 on an upper surface of the first interlayer insulating film 111. For example, as described with reference to FIG. 6, when the first interlayer insulating film 111 is etched back so that the contact plug 114 protrudes from the first interlayer insulating film 111, the plug recess is eliminated, and thus, the thickness of the second interlayer insulating film 126 is substantially the same on the first interlayer insulating film 111 and on the contact plug 114. Therefore, when the second interlayer insulating film 126 is anisotropically etched to form the cylinder hole 117, the inconvenience described above with reference to FIGS. 25A to 25C, which may occur by determining the amount of the etching according to one of the thicknesses, is less liable to occur. Therefore, a stopper film residual and overetching of the interlayer film are less liable to occur. This can reduce an increased contact resistance and an electrical continuity defect between the contact plug and the upper conductor film due to the stopper film residual. Further, a short-circuited defect between the upper conductor film and a lower member due to overetching of the interlayer film can be reduced. As a result, the manufacturing yield of the semiconductor device having a contact plug can be improved. Alternatively, as a result, the reliability of the semiconductor device having a contact plug can be improved. When the cross-sectional area of the cylinder hole 117 to be formed is larger than the cross-sectional area of the contact plug 114, the ratio of an exposed portion of the underlayer first interlayer insulating film 111 becomes larger, and thus, the effect of reducing the short-circuited defect due to overetching is more remarkable. The above description in this section holds true even when the second interlayer insulating film 126 is replaced by the etching stopper film 115.

Note that, in the above-mentioned step of forming the cylinder hole 117, in order to prevent anisotropic etching from being carried out with regard to the second interlayer insulating film 126 in the peripheral circuit region 20, a mask pattern is prepared by photolithography (the peripheral circuit region 20 is covered with the mask so as not to be etched). Further, the upper surface of the contact plug 114 illustrated in FIG. 9 protrudes from the upper surface of the first interlayer insulating film 111 and is substantially flush with an upper surface of the etching stopper film 115, but the state varies depending on the thickness of the etching stopper film 115. Specifically, when the etching stopper film 115 is thinner, the upper surface of the contact plug 114 protrudes from the etching stopper film 115, while, when the etching stopper film 115 is thicker, the upper surface of the contact plug 114 is placed lower than the upper surface of the etching stopper film 115.

In the subsequent step, various members are formed in the cylinder hole 117. In this embodiment, a step of forming a capacitive element in the cylinder hole 117 is described as an example. First, the lower electrode (electrode film) 118 formed of TiN, Ti, or the like is deposited so as to conformally cover the inner wall of the cylinder holes 117. Then, the dielectric film 119 and the upper electrode 120 are formed. Further, in the subsequent step, the contact plug 122 and the like are formed in the peripheral circuit region 20. In this way, the semiconductor device illustrated in FIG. 2 is manufactured. Note that, after the lower electrode 118 is formed, the interlayer film 116 may be removed to expose the inner and outer walls of the lower electrode 118, and the dielectric film 119 and the upper electrode 120 may be formed on both of the surfaces thereof, which is a so-called crown structure.

### Second Embodiment

A semiconductor device according to a second embodiment of this invention is, similarly to the first embodiment, a semiconductor device including the memory cell region 10 and the peripheral circuit region 20, and is similar to the semiconductor device illustrated in FIG. 1 unless otherwise indicated in the following. Therefore, description with regard to similar points is omitted.

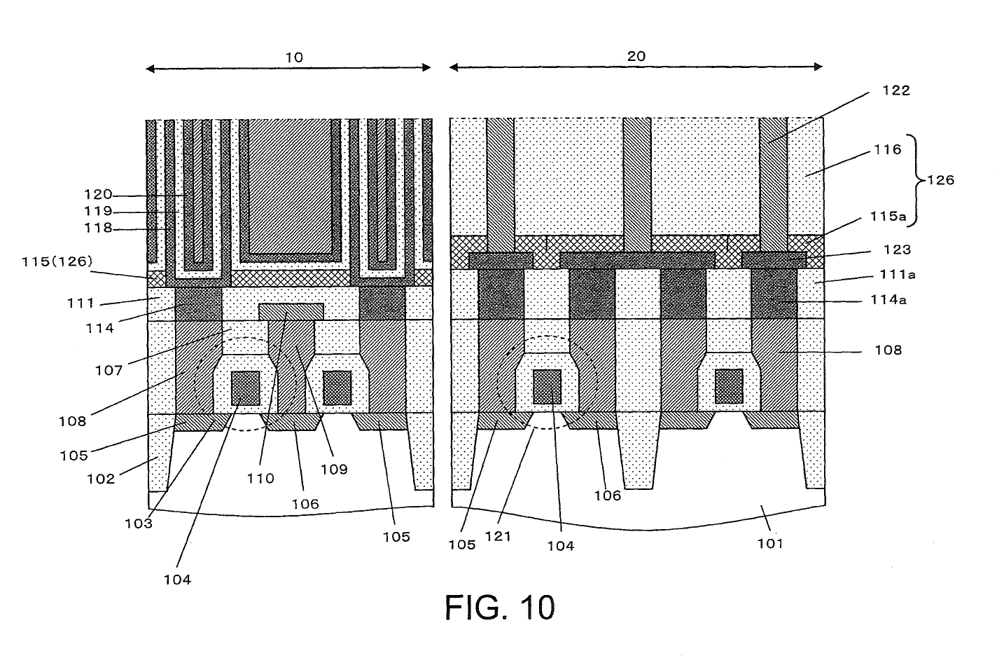

FIG. 10 is a sectional view of a main part of the semiconductor device according to the second embodiment.

In the semiconductor device according to the second embodiment, the thicknesses of the first interlayer insulating film 111 and the etching stopper film 115 formed in the memory cell region 10 are smaller than the thicknesses of a first interlayer insulating film 111a and an etching stopper film 115a formed in the peripheral circuit region 20, respectively. Further, in the peripheral circuit region 20, wiring 123 is formed on an upper surface of the first interlayer insulating film 111a. The wiring 123 is wiring for electrically connecting circuit elements (for example, the peripheral transistors 121) provided in the peripheral circuit region 20 to form various kinds of circuits.

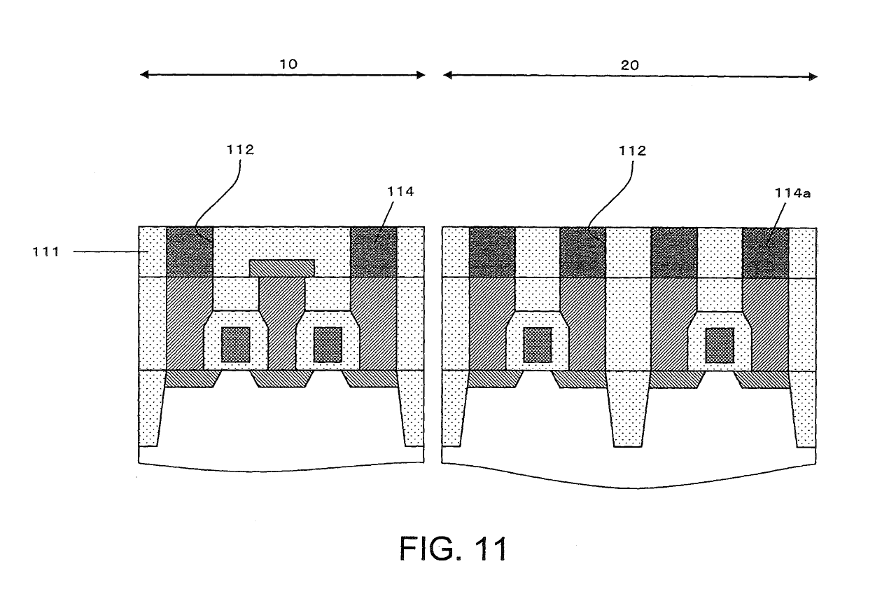

Manufacturing steps of the semiconductor device illustrated in FIG. 10 are now described with reference to FIG. 11 to FIG. 16.

FIG. 11 illustrates a manufacturing step subsequent to the manufacturing step of the semiconductor device according to the first embodiment described with reference to FIG. 3. After the step illustrated in FIG. 3, by etching back the conductor film 113, the contact plugs 114 and 114a buried in the first interlayer insulating film 111 can be formed. In FIG. 11, the upper surfaces of the contact plug 114 and the contact plug 114a for a peripheral transistor are illustrated as being flush with the upper surface of the first interlayer insulating film 111, but, as described above, when the conductor film 113 is overetched for the purpose of preventing a short between the plugs, a plug recess may occur. In the drawings which are referred to below, also, the same can be said with regard to the plug recess, which is not illustrated therein.

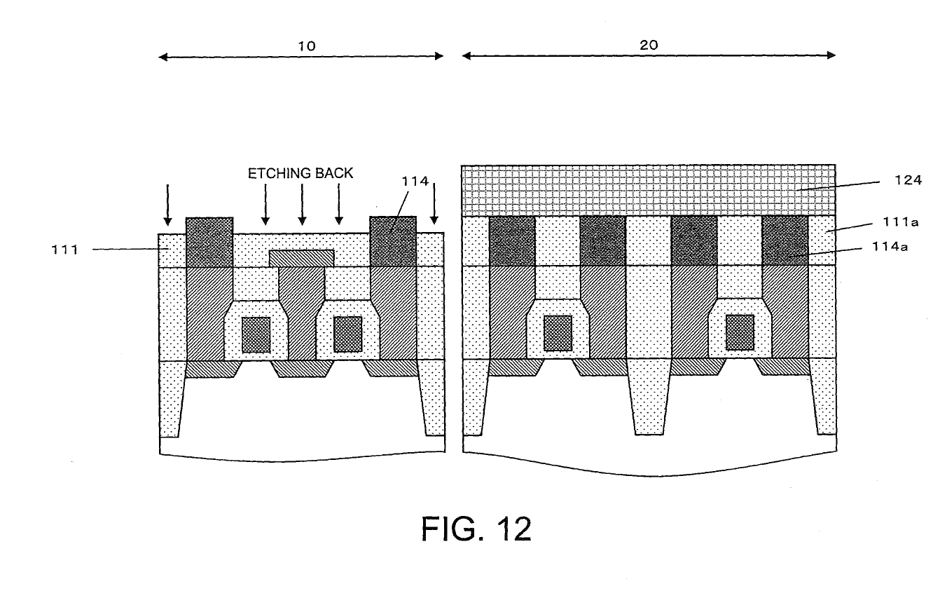

Next, a step illustrated in FIG. 12 is a step of reducing the thickness of the first interlayer insulating film 111, and corresponds to the steps described with reference to FIG. 5, FIG. 6, and FIG. 7 of the first embodiment. Note that, in the second embodiment, in the memory cell region 10, similarly to the case of the first embodiment, the thickness of the first interlayer insulating film 111 is reduced, but, in the peripheral circuit region 20, the thickness of the first interlayer insulating film 111a is not reduced. Therefore, after the contact plugs 114 and 114a are formed and before the first interlayer insulating film 111 is etched back, the peripheral circuit region 20 is covered with a photoresist 124 which is used as the etching mask. In this case, after a photoresist film is applied, patterning is carried out by ordinary photolithography. After that, by etching back the first interlayer insulating film 111, the thickness of the first interlayer insulating film 111 in the memory cell region 10 which is not covered with the photoresist 124 is reduced from the upper surface side. As a result, similarly to the case of the semiconductor device according to the first embodiment, the amount of the plug recess of the contact plug 114 in the memory cell region 10 is reduced or eliminated. On the other hand, the upper surface of the first interlayer insulating film 111a in the peripheral circuit region 20 is covered with the photoresist 124, and thus, the first interlayer insulating film 111a is not etched back. In other words, the thickness of the first interlayer insulating film 111a in the peripheral circuit region 20 does not change in this step. Therefore, the thickness of the etched back first interlayer insulating film 111 in the memory cell region 10 is smaller than the thickness of the first interlayer insulating film 111a in the peripheral circuit region 20.

As described above, according to the second embodiment, the step of etching back the upper surface of the first interlayer insulating film 111 to reduce the thickness is carried out before the step of forming wiring in the peripheral circuit region 20.

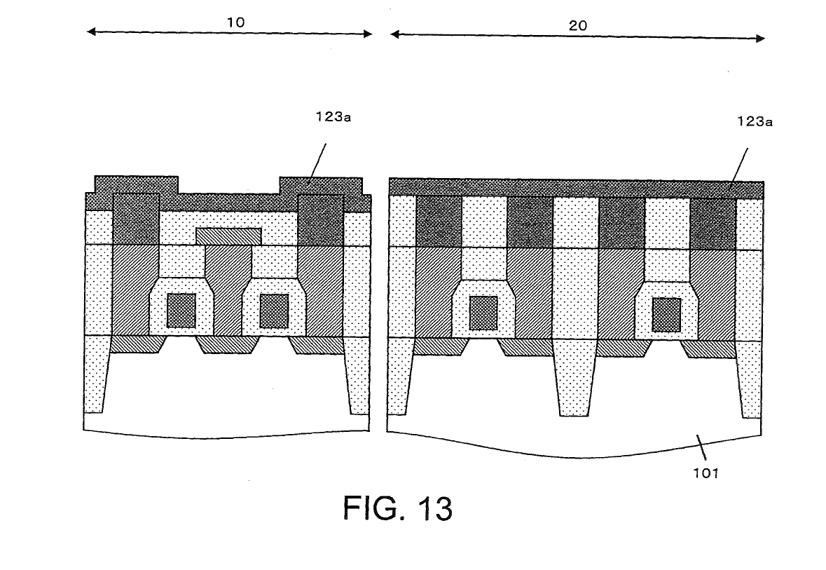

Next, after the photoresist 124 in the peripheral circuit region 20 is removed, as illustrated in FIG. 13, a conductor film (second conductive film) 123a (for the wiring in the peripheral circuit region 20) is deposited on the upper surface side of the silicon substrate 101. The conductor film 123a is, for example, formed of a conductive material such as tungsten or aluminum.

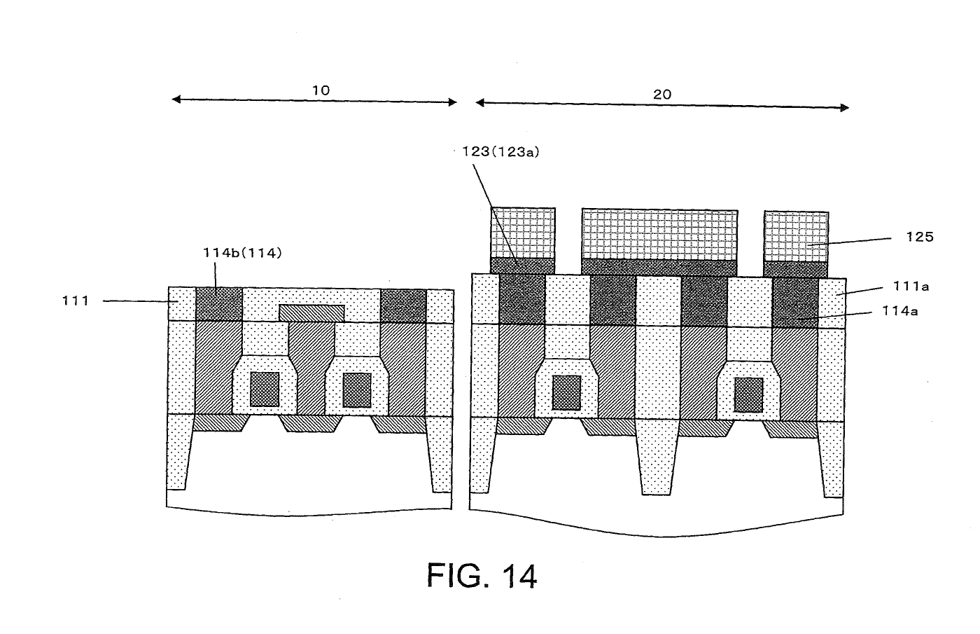

Next, as illustrated in FIG. 14, a photoresist 125 is applied onto the conductor film 123a and is patterned by well-known photolithography. In this case, the photoresist 125 is patterned in a shape which is equivalent to that of a wiring pattern to be transferred to the conductor film 123a. For example, in the memory cell region 10, when neither wiring nor pad formed of the conductor film 123a is required to be formed, the memory cell region 10 is exposed from the photoresist 125.

After that, by anisotropically etching the conductor film 123a in the thickness direction with the photoresist 125 being used as the etching mask, the wiring 123 formed of the conductor film 123a is formed. For example, in the memory cell region 10, when neither wiring nor pad formed of the conductor film 123a is required to be formed, the portion of the conductor film 123a in the memory cell region 10 which is exposed from the photoresist 125 is removed to form the wiring 123 of the conductor film 123a in the peripheral circuit region 20.

In this case, to anisotropically etch the conductor film 123a means that the thickness of the portion of the conductor film 123a which is not covered with the photoresist 125 is reduced. For example, when the contact plug 114 below the conductor film 123a is formed of the same material as that of the conductor film 123a, or, of a material having a low selectivity with regard to the anisotropic etching of the conductor film 123a, the thickness of the contact plug 114 may also be reduced during the anisotropic etching (the contact plug 114 may also be etched back from the upper surface thereof) (the contact plug 114 formed in this way in the memory cell region 10 is hereinafter referred to as contact plug 114b). In particular, when an unetched residual of the conductor film 123a remains in a portion on the first interlayer insulating film 111a formed between the wirings 123 in the peripheral circuit region 20, a short-circuited defect between the wirings may be caused. Therefore, it is preferred to remove the conductor film 123a so that the conductor film 123a is overetched to some extent. In this case, the etching is more liable to reach the contact plugs. With regard to this, according to the manufacturing method of this embodiment, the first interlayer insulating film 111 is etched back in advance in the memory cell region 10, and thus, even if the thickness of the contact plug 114b is reduced, a plug recess is less liable to occur. Specifically, by adjusting the amount of reduction of the thickness of the first interlayer insulating film 111 in the above-mentioned step described with reference to FIG. 12, even if the upper surface of the contact plug 114b is lowered by the etching back, the upper surface of the contact plug 114b can be formed higher than the upper surface of the first interlayer insulating film 111 in the memory cell region 10. In other words, a structure can be formed in which the upper surface of the contact plug 114b protrudes from the upper surface of the first interlayer insulating film 111. In this case, no plug recess of the contact plug 114b occurs. Further, even if there is some limitation on the amount of reduction of the thickness of the first interlayer insulating film 111 in the above-mentioned step described with reference to FIG. 12, it is effective to reduce the thickness even by a small amount. The reason is that, even if, due to the etching back of the contact plug 114b, the upper surface thereof becomes lower than the upper surface of the first interlayer insulating film 111 to cause a plug recess, the amount of the plug recess can be reduced by reducing the thickness of the first interlayer insulating film 111 even by a small amount. In summary, according to the manufacturing method of this embodiment, a structure can be formed in which the amount of the plug recess at the upper surface of the contact plug 114b in the memory cell region 10 is reduced or the plug recess is not caused.

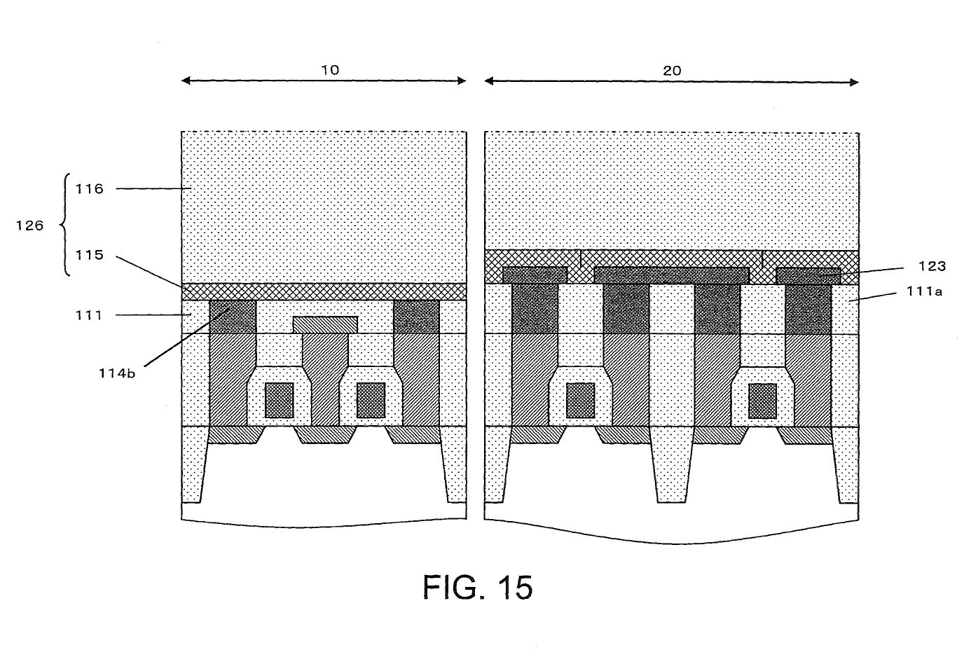

Next, after the photoresist 125 is removed, as illustrated in FIG. 15, the second interlayer insulating film (second insulating film) 126 is formed on the upper surfaces of the first interlayer insulating films 111 and 111a, on the contact plug 114b, and on the wiring 123 to cover the contact plug 114b. This step is similar to the step described with reference to FIG. 8 of the first embodiment. The structure of the second interlayer insulating film 126 (the etching stopper film 115 and the interlayer film 116) and the respective materials thereof are similar to those in the above description with reference to FIG. 8.

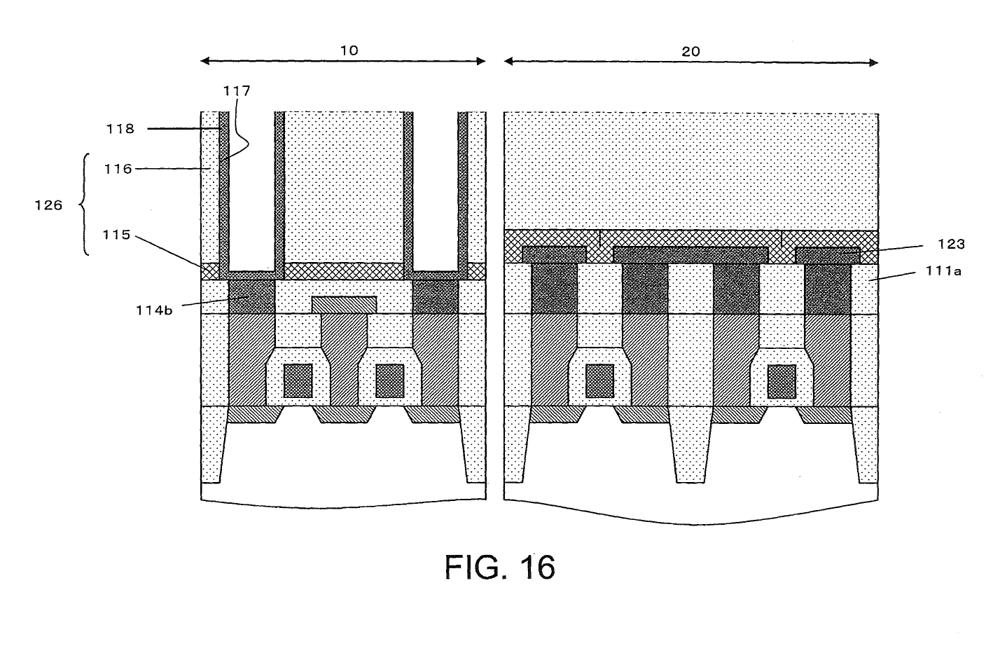

Next, as illustrated in FIG. 16, by partly removing the second interlayer insulating film 126, the cylinder hole (second opening) 117 which partly exposes the contact plug 114b in the memory cell region 10 is formed. This step is similar to the step described with reference to FIG. 9 of the first embodiment. As described with reference to FIG. 12 to FIG. 14, in this embodiment, a structure can be formed in which the amount of the plug recess of the contact plug 114b in the memory cell region 10 can be reduced or the plug recess is not caused. This can prevent a stopper film residual and overetching from easily occurring for a reason that is similar to the action and the effect described in the first embodiment. This can reduce an increased contact resistance and an electrical continuity defect between the contact plug and the upper conductor film due to the stopper film residual. Further, a short-circuited defect between the upper conductor film and a lower member due to overetching of the interlayer film can be reduced. As a result, the manufacturing yield of the semiconductor device having a contact plug can be improved. Alternatively, as a result, the reliability of the semiconductor device having a contact plug can be improved.

In a subsequent step, various kinds of members are formed in the cylinder hole 117. In this embodiment, the same step is carried out as the step of forming the capacitive element in the cylinder hole 117 of the first embodiment. In this way, the semiconductor device illustrated in FIG. 10 is manufactured.

### Third Embodiment

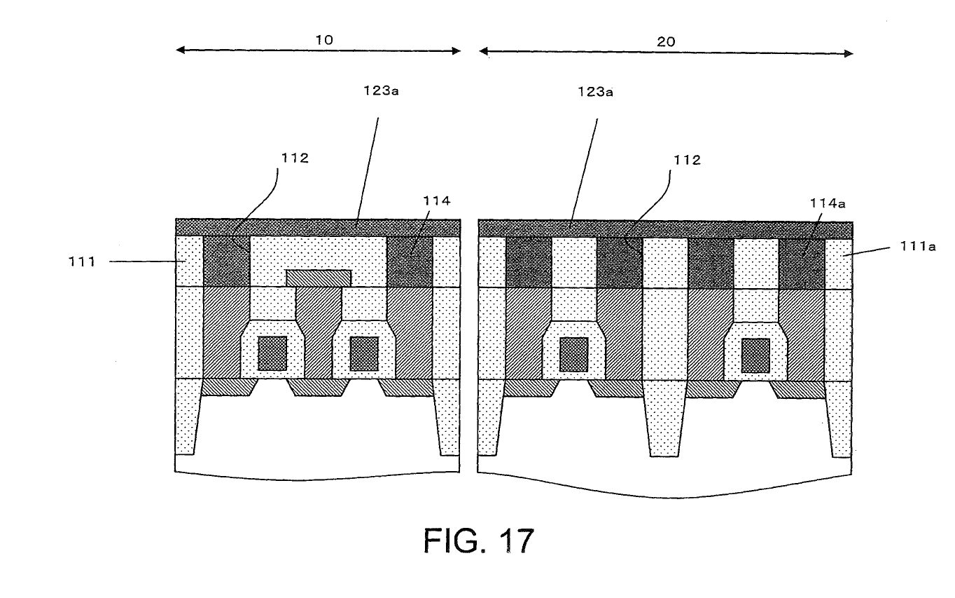

A semiconductor device according to a third embodiment of this invention is, similarly to those of the first and second embodiments, a semiconductor device including the memory cell region 10 and the peripheral circuit region 20, and the structure thereof is the same as that of the semiconductor device according to the second embodiment, which is described with reference to FIG. 10. Thus, the description thereof is omitted. FIG. 17 to FIG. 19 are sectional views of a main part of the semiconductor device according to this embodiment during manufacturing steps. In the second embodiment, before the step of forming the wiring 123 in the peripheral circuit region 20, the first interlayer insulating film 111 in the memory cell region 10 is etched back to reduce the thickness. In the manufacturing method of the third embodiment, however, after the wiring 123 in the peripheral circuit region 20 is formed, the first interlayer insulating film 111 is etched back to reduce the thickness. The manufacturing method of the third embodiment is different from that of the second embodiment only in this point. In the following, the point which is different from the manufacturing method of the second embodiment is described in detail. Steps other than the step described in the following and an action and an effect obtained by the steps are similar to those of the steps described in the first and second embodiments, and thus, description thereof is omitted here for the sake of simplicity of description.

FIG. 17 is a sectional view of the main part illustrating a manufacturing step which follows the step described with reference to FIG. 11 in the manufacturing steps according to the second embodiment and illustrating a state after a step similar to the step described with reference to FIG. 13 is carried out. Specifically, after the contact plug 114 and the contact plug 114a for a peripheral transistor are formed in the first interlayer insulating film 111 in the step illustrated in FIG. 11, the conductor film 123a is deposited in the step illustrated in FIG. 13. In FIG. 17, the upper surfaces of the contact plugs 114 and 114a are flush with the upper surface of the first interlayer insulating film 111, but, as described above, when the conductor film 113 is overetched for the purpose of preventing a short between the plugs, a plug recess may be caused. Also in the drawings which are referred to below, the same can be said with regard to the plug recess and hence the illustration thereof is omitted.

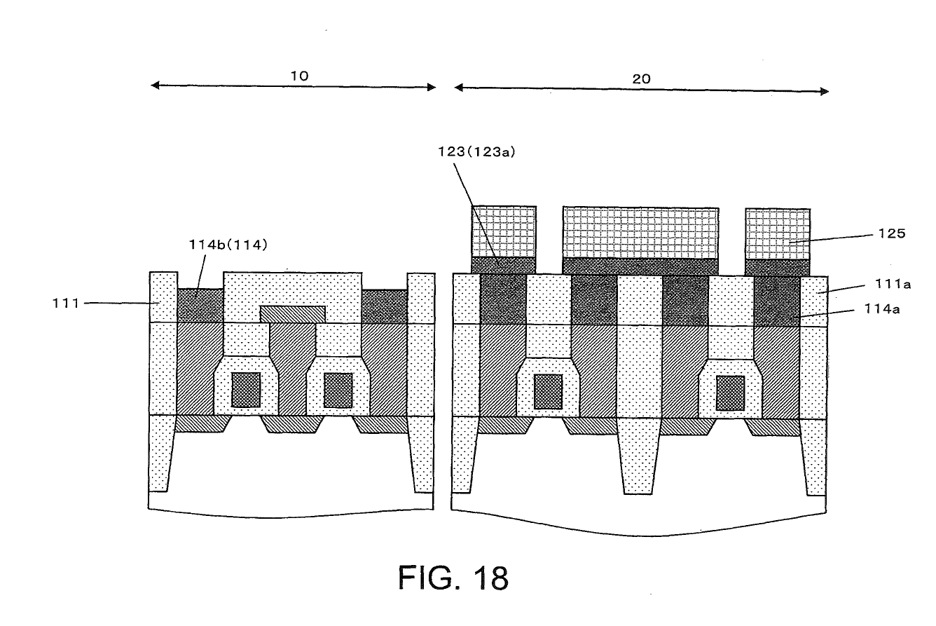

FIG. 18 is a sectional view of the main part after a step similar to the step described with reference to FIG. 14 in the manufacturing steps according to the second embodiment is carried out following the step illustrated in FIG. 17. Specifically, in the step illustrated in FIG. 14, the patterned photoresist 125 is formed on the conductor film 123a, and, with the photoresist 125 being used as the etching mask, the conductor film 123a is anisotropically etched in the thickness direction to form the wiring 123 of the conductor film 123a.

For example, in the memory cell region 10, when neither wiring nor pad formed of the conductor film 123a is required to be formed, the entire conductor film 123a in the memory cell region 10 which is exposed from the photoresist 125 is removed by etching back. Further, for example, when the contact plug 114 below the conductor film 123a is formed of the same material as that of the conductor film 123a, or, of a material having a low selectivity with regard to the anisotropic etching of the conductor film 123a, the thickness of the contact plug 114 may also be reduced during the anisotropic etching (the contact plug 114 may also be etched back from the upper surface thereof) (the contact plug 114 formed in this way in the memory cell region 10 is hereinafter referred to as contact plug 114b). In particular, when an unetched residual of the conductor film 123a remains in a portion on the first interlayer insulating film 111a between the wirings 123 in the peripheral circuit region 20, a short-circuited defect between the wirings may be caused, and thus, it is preferred to remove the conductor film 123a so that the conductor film 123a is overetched to some extent. In this case, the etching is more liable to reach the contact plugs. As a result, the upper surface of the contact plug 114b in the memory cell region 10 is lowered to be lower than the upper surface of the first interlayer insulating film 111. Thus, a plug recess becomes more liable to occur.

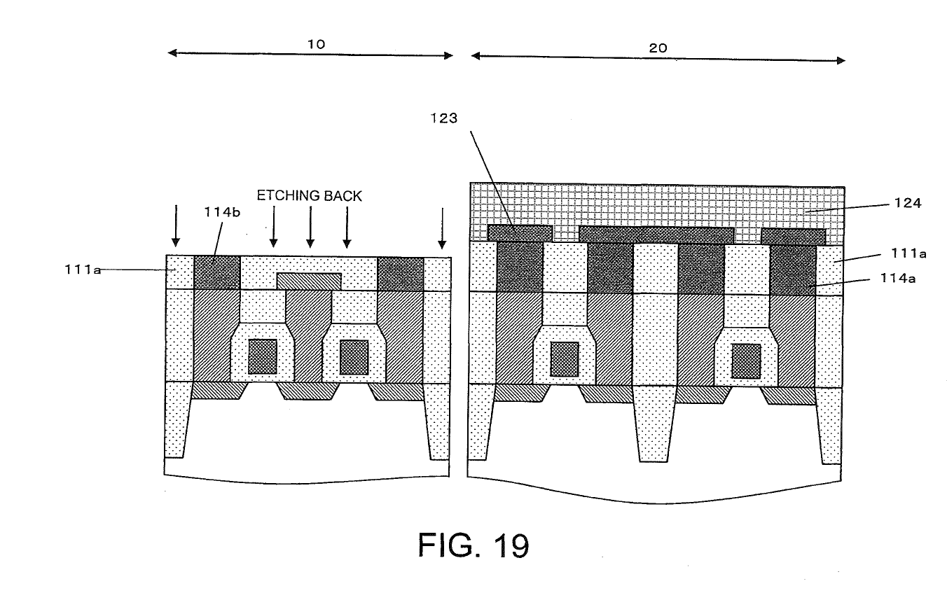

FIG. 19 is a sectional view of the main part after a step similar to the step described with reference to FIG. 12 in the manufacturing steps according to the second embodiment is carried out following the step illustrated in FIG. 18. Specifically, the peripheral circuit region 20 is covered with the photoresist 124, and, with the photoresist 124 being used as the etching mask, the first interlayer insulating film 111 is etched back to reduce the thickness of the first interlayer insulating film 111 in the memory cell region 10 which is not covered with the photoresist 124 from the upper surface side. As a result, similarly to the case of the semiconductor device according to the first embodiment, the amount of the plug recess of the contact plug 114b in the memory cell region 10 is reduced or eliminated. On the other hand, the upper surface of the first interlayer insulating film 111a in the peripheral circuit region 20 is covered with the photoresist 124, and thus, the first interlayer insulating film 111a is not etched back. In other words, the thickness of the first interlayer insulating film 111a in the peripheral circuit region 20 does not change in this step. Therefore, the thickness of the etched back first interlayer insulating film 111 in the memory cell region 10 is smaller than the thickness of the first interlayer insulating film 111a in the peripheral circuit region 20.

As described above, according to the third embodiment, the step of etching back the upper surface of the first interlayer insulating film 111 in the memory cell region 10 to reduce the thickness is carried out after the step of patterning the conductor film 123a to form the wiring 123 in the peripheral circuit region 20. According to this method, when the conductor film 123a is anisotropically etched to form the wiring 123, the upper surface of the contact plug 114b in the memory cell region is lowered, and the difference with the upper surface of the first interlayer insulating film 111 (plug recess) is canceled out by etching back the first interlayer insulating film 111. Specifically, the amount of the plug recess can be reduced or eliminated. In other words, after the contact plug 114 is etched through the conductor film 123a, by reducing the thickness of the first interlayer insulating film 111, the amount of the plug recess can be reduced. By reducing the thickness of the first interlayer insulating film 111 by an amount which is larger than the amount of the plug recess, the plug recess can be eliminated. This can cause a stopper film residual and overetching to be less liable to occur for a reason that is similar to the action and the effect described in the first embodiment. This can reduce an increased contact resistance and an electrical continuity defect between the contact plug and the upper conductor film due to the stopper film residual. Further, a short-circuited defect between the upper conductor film and a lower member due to overetching of the interlayer film can be reduced. As a result, the manufacturing yield of the semiconductor device having a contact plug can be improved. Alternatively, as a result, the reliability of the semiconductor device having a contact plug can be improved.

By carrying out the manufacturing steps described in the second embodiment with reference to FIG. 15 and FIG. 16, a semiconductor device similar to that illustrated in FIG. 10 is manufactured.

### (Modification)

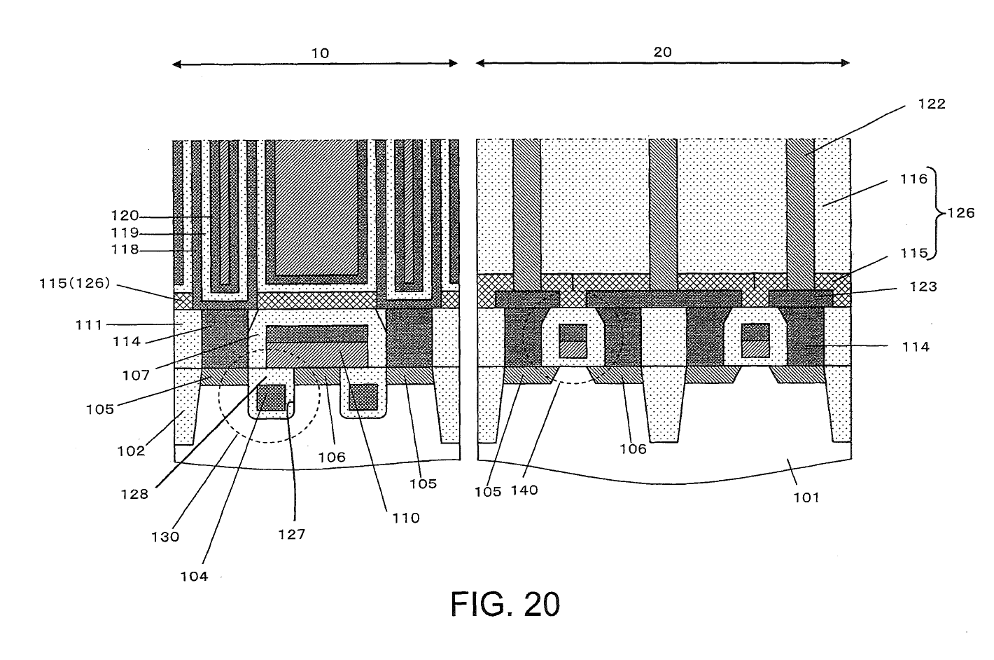

The invention of this application is effective when applied to a semiconductor device having a structure in which a cylinder hole for forming therein a member to be connected to a contact plug is formed on the contact plug buried in an interlayer insulating film as in the semiconductor devices according to the first, second and third embodiments, and is not limited to the structures in the above-mentioned embodiments. For example, in the above-mentioned embodiments, the transistor formed on the silicon substrate 101 is a planar field-effect transistor, but the invention of this application is similarly effectively applied to transistors having other structures. As an example, a modification in which the cell transistor in the memory cell region is replaced by a buried gate field-effect transistor is described. FIG. 20 is a sectional view of a main part of a semiconductor device in which the cell transistors 103 in the memory cell region 10 of the semiconductor device according to the second or third embodiment described with reference to FIG. 10 or the like are replaced by buried gate field-effect transistors 130.

As illustrated in FIG. 20, the semiconductor device of this modification includes, in the memory cell region 10, the buried gate transistors 130 in which the gate electrodes (word lines) 104 are buried below the surface of the silicon substrate 101 as two transistors which form two memory cells. More specifically, the buried gate transistors 130 of this modification include grooves (trenches) 127 which are formed so as to cross and divide into two the active region in the main surface of the silicon substrate 101. A conductor film is formed at the bottom of the groove 127 via a gate insulating film for covering the inner wall. The conductor film functions as the gate electrode 104. As the gate electrode 104, a material such as tungsten or conductive polysilicon can be used. An upper portion of the gate electrode 104 is covered with a burying insulating film 128 in the groove 127, thereby being buried in a bottom portion of the groove 127. When a predetermined potential is supplied to the gate electrode 104, due to the field effect, an inversion layer (channel) is formed via the gate insulating film in a portion of the active region (silicon) which is adjacent to the gate electrode 104. By forming two semiconductor regions having a conductivity type opposite to that of the active region so as to be in contact with a region in which the inversion layer is to be formed and so as to be connected via the inversion layer, carriers can be given and received between the two regions. In other words, a field-effect transistor in which the two regions are source/drain regions can be formed. In this case, among the active regions divided by the groove 127 in which the gate electrode 104 is formed, active regions which are higher than the portions adjacent to the gate electrode 104 are set to have the opposite conductivity type, and are formed as the source region 105 and the drain region 106, respectively. Two cell transistors 130 formed in one active region are similar to those in the above-mentioned embodiments in that the drain region 106 is shared. Further, it is also similar to the cases of the above-mentioned embodiments in that, although the source region 105 and the drain region 106 are discriminated for the sake of convenience, there is no difference in structure between the source region and the drain region.

The semiconductor device of this modification includes the bit line 110 which is held in contact with an upper surface of the drain region 106 shared by the two cell transistors 130 and is placed on a main surface of the silicon substrate 101. In the case of a planar transistor, the gate electrode of a cell transistor which forms the word line is placed on the silicon substrate, and thus, the bit line is placed in a layer thereabove via the interlayer insulating film. On the other hand, in the case of a buried gate transistor, the gate electrode of a cell transistor which forms the word line is buried in the silicon substrate, and thus, the bit line can be placed on the substrate. This modification has such a structure. The bit line 110 has a multilayer structure including, for example, a conductive polysilicon layer and a tungsten layer.

On the other hand, in the peripheral circuit region 20, differently from the cell transistor 130 in the memory cell region 10, a planar peripheral transistor 140 is formed. Specifically, the peripheral transistor 140 formed in the peripheral circuit region 20 includes a gate insulating film and a gate electrode (word line) formed on the silicon substrate 101. The illustrated gate electrode may partly include a structure similar to that of the bit line 110 such as a multilayer structure including a polysilicon layer and a tungsten layer. Other principal points of the structure of the peripheral transistor 140 are similar to those in the above-mentioned embodiments.

As described above, in this modification, the cell transistor 130 in the memory cell region 10 is a buried gate transistor in which the gate electrode is buried in the silicon substrate, and thus, a layer including the contact plug and a layer including the wiring on the substrate can be lowered by one layer from those in the above-mentioned embodiments. Specifically, for example, in FIG. 10, the layer including the bit line 110 is placed over the main surface of the silicon substrate 101 with one interlayer insulating film therebetween, while, in the structure illustrated in FIG. 20, the layer including the bit line 110 can be lowered by one layer and can be placed on the main surface of the substrate. Therefore, the first interlayer insulating film 111 which includes therein the bit line 110 and has the contact plug 114 can be replaced by a layer on the main surface of the silicon substrate 101. It follows that the first interlayer insulating film 111 according to the invention of this application is, in the structure of this modification, an interlayer film on the main surface of the silicon substrate 101. A capacitor including the lower electrode (electrode film) 118, the dielectric film 119, and the upper electrode 120 is provided on the first interlayer insulating film 111 via the contact plug 114.

As described above, the invention of this application can be similarly effectively applied to the semiconductor device including the buried gate transistor 130. As described in the second embodiment or the third embodiment, the first interlayer insulating film 111 is etched back to reduce the thickness thereof from the upper surface side after the contact plug 114 in the memory cell region 10 is formed in the first interlayer insulating film 111 and before the second interlayer insulating film 126 is formed. By the step of burying the contact plug 114 in the first interlayer insulating film 111, or, by the step of forming the wiring 123 in the peripheral circuit region 20, a plug recess which may be caused on the upper surface of the contact plug 114 can be canceled out. With this state, after the second interlayer insulating film 126 including the etching stopper film 115 and the interlayer film 116 is formed, the cylinder hole 117 is provided. This can cause a stopper film residual and overetching to be less liable to occur for a reason that is similar to the action and the effect described in the first embodiment. This can reduce an increased contact resistance and an electrical continuity defect between the contact plug and the upper conductor film due to the stopper film residual. Further, a short-circuited defect between the upper conductor film and a lower member due to overetching of the interlayer film can be reduced. As a result, the manufacturing yield of the semiconductor device having a contact plug can be improved. Alternatively, as a result, the reliability of the semiconductor device having a contact plug can be improved.

The step of etching back the first interlayer insulating film 111 to reduce the thickness thereof may be carried out before the step of forming the wiring 123 in the peripheral circuit region 20 as described in the second embodiment, or, may be carried out after the step of forming the wiring 123 in the peripheral circuit region 20 as described in the third embodiment.

In the embodiments described above, a DRAM is described in which the memory cell region 10 and the peripheral circuit region 20 are integrally formed on the same silicon substrate 101, but it goes without saying that this invention is applicable similarly to a general-purpose DRAM in which only the memory cell region 10 is formed on the silicon substrate 101. Further, it goes without saying that the materials of the interlayer insulating films and the conductor films in the embodiments described above can be appropriately changed to other materials.

This invention is widely applicable to semiconductor devices necessary for processing information in, for example, a personal computer and mobile equipment.

Although preferred embodiments of the present invention have been described above, the present invention is not limited to the aforementioned exemplary embodiments. As a matter of course, various modifications can be made therein without departing from the spirit of the present invention, and those modifications should be included in this present invention.

This application is based upon and claims the benefit, of priority from Japanese patent application No. 2012-185403, filed on Aug. 24, 2012, the disclosure of which is incorporated herein in its entirety by reference.

1. A semiconductor device, comprising:
a first transistor comprising a source region and a drain region both formed on a semiconductor substrate;
a first interlayer insulating film formed so as to cover the first transistor;
a first contact hole formed in the first interlayer insulating film so as to expose one of the source region and the drain region;
a first contact plug which is formed in the first contact hole, and which has a lower portion connected to the exposed one of the source region and the drain region, and an upper portion comprising a protruding portion which protrudes from the first interlayer insulating film; and
a capacitive element formed so that an electrode thereof is electrically connected to an upper surface portion of the first contact plug.

2. A semiconductor device according to claim 1, further comprising an etching stopper film which is formed on the first interlayer insulating film, the etching stopper film being formed so as to cover a side surface portion of the protruding portion of the first contact plug except for the upper surface portion.

3. A semiconductor device according to claim 2, further comprising a second interlayer insulating film formed on the etching stopper film.

4. A semiconductor device according to claim 3, wherein a main material of the etching stopper film and a main material of the second interlayer insulating film are different from each other.

5. A semiconductor device according to claim 3, wherein the etching stopper film is thinner than the second interlayer insulating film.

6. A semiconductor device according to claim 4, wherein a main material of the etching stopper film is silicon nitride and a main material of the second interlayer insulating film is silicon oxide.

7. A semiconductor device according to claim 3, wherein the capacitive element is formed in a cylinder hole formed in the second interlayer insulating film.

8. A semiconductor device according to claim 3, further comprising:
a second transistor comprising a source region and a drain region both formed on the semiconductor substrate;
a second contact hole formed in the first interlayer insulating film so as to expose one of the source region and the drain region of the second transistor; and
a second contact plug which is formed in the second contact hole, and which has a lower portion connected to the exposed one of the source region and the drain region of the second transistor, and an upper portion comprising a protruding portion which protrudes from the first interlayer insulating film.

9. A semiconductor device according to claim 8, further comprising a through hole formed so as to pierce the second interlayer insulating film,
wherein the etching stopper film is formed on a side surface portion and an upper surface portion of the second contact plug except for the through hole.

10. A semiconductor device according to claim 8, wherein the first transistor is formed in a memory region and the second transistor is formed in a peripheral region.

11. A semiconductor device, comprising:
a first transistor comprising a source region and a drain region both formed on a semiconductor substrate;
a first interlayer insulating film formed so as to cover the first transistor;
a first contact hole formed in the first interlayer insulating film so as to expose one of the source region and the drain region;
a first contact plug which is formed of a conductive material in the first contact hole;
a second contact hole formed in the first interlayer insulating film so as to expose another one of the source region and the drain region;
a second contact plug which is formed of the conductive material in the second contact hole;
a second interlayer insulating film formed on the first interlayer insulating film;
a third contact hole formed in the second interlayer insulating film so as to be coincident with, in plan view, the first contact hole;
a third contact plug which is formed in the third contact hole, and which has a lower portion connected to the first contact plug, and an upper portion protruding from the second interlayer insulating film; and
a capacitive element comprising an electrode electrically connected to the third contact plug.

12. A semiconductor device according to claim 11, further comprising an etching stopper film which is formed on the second interlayer insulating film, the etching stopper film being formed so as to cover a side surface portion of the protruding portion of the third contact plug except for the upper surface portion.

13. A semiconductor device according to claim 12, further comprising a third interlayer insulating film formed on the etching stopper film.

14. A semiconductor device according to claim 13, wherein a main material of the etching stopper film and a main material of the third interlayer insulating film are different from each other.

15. A semiconductor device according to claim 13, wherein the etching stopper film is thinner than the third interlayer insulating film.

16. A semiconductor device according to claim 14, wherein a main material of the etching stopper film is silicon nitride and a main material of the third interlayer insulating film is silicon oxide.

17. A semiconductor device according to claim 13, wherein the capacitive element is formed in a cylinder hole formed in the third interlayer insulating film.
